(19) United States
(12) Patent Application Publication
(10) Pub. No.: US 2022/0341551 A1
(43) Pub. Date: Oct. 27, 2022

(54) LIGHTING SYSTEM FOR THE EVENLY DISTRIBUTED EMISSION OF LIGHT FROM LIGHT SOURCES

(71) Applicant: LightnTec GmbH, Karlsruhe (DE)

(72) Inventor: Lutz Nehrhoff von Holderberg, Karlsruhe (DE)

(73) Assignee: LightnTec GmbH, Karlsruhe (DE)

(21) Appl. No.: 17/806,890

(22) Filed: Jun. 14, 2022

Related U.S. Application Data
(63) Continuation of application No. PCT/EP2020/081204, filed on Nov. 5, 2020.

(30) Foreign Application Priority Data
Dec. 23, 2019 (DE) 10 2019 220 571.2

(51) Int. Cl. F21K 9/64; F21V 13/14; F21V 9/38

(52) U.S. Cl. CPC F21K 9/64; F21V 13/14; F21V 9/38; F21Y 2115/10

(57) ABSTRACT

A lighting system is disclosed for the spatially evenly distributed emission of light from first, second and third light sources. The spectral ranges of the light emitted by the different light sources are different from each other. The lighting system includes: a holding layer or carrier layer, on which the light sources are arranged in groups each having one each of the first, second and third light sources; and a luminophore layer, which is arranged in the propagation direction of the light from the light sources and has a first, a second and a third luminescent-material film. The luminescent material of each luminescent-material film is induced to luminesce largely, more particularly exclusively, by means of the first, second or third light sources.

### CROSS-REFERENCE TO RELATED APPLICATIONS

This continuation application claims priority to PCT/EP2020/081204 filed on Nov. 5, 2020 which has published as WO 2021/129971 A1 and also the German application number 10 2019 220 571.2 filed on Dec. 23, 2019, the entire contents of which are fully incorporated herein with these references.

### DESCRIPTION

### Field of the Invention

The invention relates to a lighting system for the spatially evenly distributed emission of light from light sources which emit light in different spectral ranges.

### Background of the Invention

Lighting systems in which light from an array of lasers is radiated onto a screen are known from the prior art. The screen consists of materials which include plastics material and glass and are coated with strips of luminescent material. The laser beams pass over the screen line by line. The laser beams cause the strips of luminescent material to luminesce, so that an image is generated.

These lighting systems comprise a comparatively large-scale and rigid projection assembly.

### SUMMARY OF THE INVENTION

Object of the invention:

The object of the present invention is that of providing a lighting system which is compact and can be flexibly adapted to its surroundings.

Description of the invention:

This object is achieved according to the invention by a lighting system of the type mentioned at the outset, the lighting system comprising:

a) light sources of a first type, which emit light in a first spectral range,

b) light sources of a second type, which emit light in a second spectral range,

c) light sources of a third type, which emit light in a third spectral range,

d) a carrier layer, on which the light sources are arranged in groups which are regularly spaced apart from each other, each group comprising three light sources and, in each group, each light source belonging to a different one of the three types than the other light sources in the group,

e) a luminescent-material layer arranged in the beam direction of the light sources, comprising
i. a first luminescent material, in particular in a first luminescent-material film, which is caused to luminesce by the light sources of the first type,
ii. a second luminescent material, in particular in a second luminescent-material film arranged on the first luminescent-material film in the beam direction of the light sources, which is caused to luminesce by the light sources of the second type,
iii. a third luminescent material, in particular in a third luminescent-material film arranged on the second luminescent-material film in the beam direction of the light sources, which is caused to luminesce by the light sources of the third type.

The lighting system is compact and produces a homogeneous illumination of the luminescent-material layer in an energy-efficient, in particular CO2-neutral manner. The lighting system is flexible and simple to install. The illumination is largely independent of the distances between the groups of the light sources. Large beam angles can be achieved using the lighting system. The lighting system can be used as background illumination.

The luminescent-material layer in particular comprises the first, second and third luminescent-material film. The light sources in particular comprise laser diodes or light-emitting diodes. The luminescent materials are in particular caused to luminesce in each case for the light emitted by a light source of one type and are largely, in particular completely, transparent with respect to the light sources of the other types. The luminescent materials in particular luminesce by means of the mechanism of phosphorescence or fluorescence. Luminescent materials are preferably used in which the duration of the afterglow in the case of phosphorescence is 1 millisecond or less. In particular, the different spectral ranges of the radiation emitted by the different light sources have different limits. The different spectral ranges preferably have intensity maxima of the emitted radiation for different wavelengths. The lighting system is in particular a stretch ceiling or light-emitting wallpaper or illuminated wallpaper. The carrier layer is in particular designed as a carrier film. The light sources are in particular arranged within the groups at a smaller distance than the distance between the groups. The groups of light sources are in particular arranged in a pixel structure, with each pixel being associated with a group of light sources. The groups can also comprise more than three light sources, in particular light sources which are different from each other. Light is in particular understood to mean the part of the electromagnetic spectrum that is visible to the human eye. However, the invention also includes radiation sources which emit radiation in a different range of the electromagnetic spectrum.

Preferred Embodiments and Further Developments:

In an advantageous embodiment of the lighting system, the luminescent-material layer is spaced apart from the light sources at a smaller distance than the distance between the groups of the light sources. An air layer or vacuum is in particular located between the luminescent-material layer and the carrier layer. Due to the comparatively thin design in the direction from the carrier layer to the luminescent-material layer, such a lighting system can be installed in a space-saving manner.

A further advantageous embodiment is characterized in that the luminescent-material layer is arranged directly on a further component of the lighting system, in particular the carrier layer, in the direction of the carrier layer. A component of the lighting system in particular comprises a layer of the lighting system or a film. Such a lighting system is particularly thin.

In preferred embodiments, a micro-optical system for deflecting light is arranged between the luminescent-material layer and the light sources. The micro-optical system is used to scatter the light and thus provides a more homogeneous distribution, in particular when there is a comparatively small distance or no distance between the light sources and the luminescent-material layer.

The micro-optical system according to the invention comprises micro-optical components which have lens structures, prism structures, polarizer structures, filter structures, phase plate structures, mirror structures, diaphragm structures, lattice structures, fibers and/or light guides for guiding the light introduced into the micro-optical system. The micro-optical components obtain their micro-optical function by shaping and/or changing the refractive index of an optically even starting material, in particular an acrylic film.

The shaping can be carried out by means of classic methods such as melting, grinding, drawing, etching, pressing and/or polishing. The list is not to be understood as exhaustive with regard to the methods mentioned.

Using the micro-optical components, in particular by means of an arrangement of a plurality of micro-optical structures, the micro-optical system guides the light introduced into the micro-optical system via defined optical paths. An optical path determines the exit point and exit angle of a light beam depending on the entry point and the entry angle. The difference with regard to a conventional diffuser is the inhomogeneous beam guidance through the micro-optical system, while a diffuser is characterized by a homogeneous beam path.

For this purpose, the micro-optical system comprises a structured surface having repeating micro-optical regions. The micro-optical regions are used to deflect the light introduced into the micro-optical system at different angles. The micro-optical regions are preferably predominantly rotationally symmetrical, in particular circular and/or elliptical, starting from an optical center which is close to, in particular precisely above, a light-emitting diode. The micro-optical regions have a larger area than the light-emitting diodes.

The dimensions of the micro-optical regions are adapted to the distance between the light-emitting diodes and can differ in the directions of extension of the micro-optical system. In particular, the direction-dependent dimension of the micro-optical regions corresponds at least to the distance between the light-emitting diodes in this direction of extension of the micro-optical system. It can thus be ensured that the light emitted by the light-emitting diodes is reliably deflected by at least up to half of the distance between the light-emitting diodes.

The light emitted by the light-emitting diodes can be used particularly effectively if the adjacent micro-optical regions overlap. As a result, light can be used with very large beam angles.

The micro-optical system can consist of glass, quartz glass, polymers, in particular acrylic, and/or silicon. The use of crystals is also conceivable. By using polymers, the costs for the production of the micro-optical system can be reduced in a particularly advantageous manner.

The term “light-emitting diode” is used here to represent all light-emitting diodes, including laser diodes, diode modules, diode components (dies), etc. It is known to a person skilled in the art that the use of more specific light-emitting diode dies can lead to modifications to the lighting system. The term “light-emitting diode” also refers to all colors of light-emitting diodes and combined colors in light-emitting diode dies.

In a further embodiment, a diffuser layer for scattering light is arranged on the luminescent-material layer, in particular on the side of the luminescent-material layer that faces away from the carrier layer. The diffuser layer also enhances the homogenization of the light emitted by the lighting system.

In a preferred embodiment, the first luminescent-material film comprises blue-light-emitting luminescent material, the second luminescent-material film comprises green-light-emitting luminescent-material and the third luminescent-material film comprises red-light-emitting luminescent material, in particular, the first luminescent-material film being arranged closer to the carrier layer than the second luminescent-material film and the second luminescent-material film being arranged closer to the carrier layer than the third luminescent-material film. Any color can be produced by combining the radiation emitted in each case by these luminescent-material films.

The light sources are advantageously designed as light-emitting diodes. Light-emitting diodes are characterized by a long service life and low energy consumption as well as a narrow-band emission spectrum.

In a further embodiment of the lighting system, the light sources emit light in the blue range of the optical spectrum, the intensity maxima of the light emitted by the light sources of the first, second and third type in particular differing from each other and preferably being in a spectral range from 380 nm to 480 nm, in particular, the maximum intensity of the light source of the first type being 405 nm to 422 nm, preferably 410 nm, the maximum intensity of the light source of the second type being 425 nm to 442 nm, preferably 430 nm, and the maximum intensity of the light source of the third type being 445 nm to 460 nm, preferably 450 nm. Blue light is in particular strongly scattered, so that the light already reaches the luminescent-material films in a comparatively evenly distributed manner.

The groups of the light sources are preferably arranged in a rectangular pattern. The groups are in particular arranged in a square pattern. The pattern is in particular in the form of a matrix. In the case of such an arrangement of the light sources, the radiation emitted by the light sources and impinging on the luminescent-material layer is already distributed comparatively homogeneously.

The light sources are preferably designed to be operated with pulse width modulation. In particular, the light sources are switched on and off at a predetermined frequency which is preferably imperceptible to the human eye. This in particular influences the perceived brightness of the light sources and thus of the lighting system.

In a further embodiment, the carrier layer comprises a metal, in particular copper. The carrier layer in particular comprises a copper matrix and/or indium tin oxide and/or a printed silver layer for forming an, in particular flexible, circuit board for the light sources.

In a further embodiment, the lighting system comprises a multilayer luminous film having a plurality of light-emitting diodes, a conductor layer for electrically connecting the light-emitting diodes, and a carrier layer, the luminous film comprising a first micro-optical layer for generating homogeneous illumination. The first micro-optical layer is in particular designed as a micro-optical system or a further micro-optical system.

An embodiment is preferred in which the luminous film comprises a textile layer or a non-woven fabric layer on the light-emitting film surface. A textile layer or non-woven fabric layer makes particularly homogeneous illumination of the luminous film possible and also has acoustic advantages.

In a preferred further development, the textile layer or the non-woven fabric layer is formed by flocking the luminous film. By means of flocking, the textile layer or the non-woven fabric layer can be produced in a particularly simple and cost-effective manner during the production of the luminous film. It is also conceivable to apply the flocking only at a later point in time after the luminous film has been produced, for example after the luminous film has been installed. As a result, the textile layer or non-woven fabric can be protected against damage particularly well.

In a particularly preferred further development, the flocking consists of a mixed granular material of a wide variety of granular bodies and/or fibers. In this way, an irregular design of the flocking can be implemented in a particularly advantageous manner, which promotes a particularly high level of sound absorption by the luminous film. Alternatively or additionally, the granular material can consist of translucent, in particular transparent, granular bodies and/or fibers, as a result of which the illumination of the luminous film can also be improved.

As an alternative or in addition to a textile layer, a non-woven fabric and/or a woven fabric, a top layer, in particular a silicate render, liquid wallpaper, antibacterial layer and/or anti-adhesive layer can be provided.

Furthermore, an embodiment is preferred in which the first micro-optical layer predominantly, in particular completely, encloses the light-emitting diodes. As a result, the light emitted by the light-emitting diodes can be guided particularly effectively through the micro-optical layer, the loss of light can be reduced, and the evenness of the illumination of the luminous film can be further increased.

The micro-optical layer is preferably in the form of a stamped and/or pressed layer. Alternatively or in addition thereto, the micro-optical layer can be formed in one piece. The micro-optical components can be in the form of planar, integrated optics of the micro-optical layer.

In a preferred embodiment, the luminous film comprises a mirror layer which is located behind the light-emitting diodes in the emission direction of the luminous film. Such a mirror layer reflects light emitted counter to the direction of illumination of the luminous film and ensures even more effective and low-loss use of the light emitted by the light-emitting diodes.

In a particularly preferred embodiment, the mirror layer and the carrier layer form a common layer. This allows the luminous film to be produced particularly efficiently and cost-effectively because the mirror layer is already produced during the production of the carrier layer. In this way, the mirror layer can also be designed to be particularly thin.

When using a mirror layer, the micro-optical layer can be arranged particularly effectively behind the light-emitting diodes and in front of the mirror layer in the emission direction of the luminous film. As a result, the optical path through the micro-optical layer can be lengthened or the micro-optical layer can be designed to be particularly thin. In this case, the light emitted by the light-emitting diodes counter to the emission direction of the luminous film is first guided counter to the emission direction of the luminous film to the mirror layer through the micro-optical layer. The mirror layer reflects the incoming light in the emission direction of the luminous film, as a result of which the light is guided through the micro-optical layer once more to finally emerge on the surface of the luminous film. As a result, the effectiveness of the light guidance is further increased by the micro-optical layer and the proportion of the light used.

An embodiment is preferred in which the film comprises a further micro-optical layer having micro-optical components, the light-emitting diodes being arranged between the two micro-optical layers. As a result, effective light guidance can be implemented in a particularly favorable manner, and the production complexity can be reduced to the arrangement of the layers.

An embodiment is particularly preferred in which the carrier layer consists of a film, a non-woven fabric and/or a woven fabric, in particular a textile, particularly preferably a paper. This offers the advantage of a wide range of applications, because the carrier layer can be adapted to the prevailing conditions at the place of use. In a particular further development, the carrier layer can be translucent, in particular completely transparent. As a result, the luminous effect of the luminous film can be achieved on both sides.

An embodiment is also preferred in which the conductor layer is designed to be partially translucent, in particular completely translucent. The translucence of the conductor layer allows it to be arranged in front of the light-emitting diodes in the emission direction of the luminous film, without the conductor tracks interfering with the luminous effect of the luminous film.

In a preferred embodiment, the conductor layer can consist of copper, electrically conductive ink, indium zinc oxide and/or silver oxide.

Furthermore, an embodiment is preferred in which the textile layer or the non-woven fabric layer is unidirectionally translucent, in particular in the emission direction of the luminous film. As a result, the luminous effect of the luminous film can be achieved in a particularly even manner.

An embodiment is particularly preferred in which the textile layer or the non-woven fabric layer is at least in part of high acoustic impedance and/or low acoustic impedance. This allows the use of the luminous film in regions having acoustic specifications or to improve the acoustic conditions. Depending on the specification, the textile layer can therefore be designed to be sound-absorbing and/or sound-reflecting.

In one embodiment, the light-emitting diodes are at a distance of between 1 millimeter and 200 millimeters, in particular between 4 millimeters and 150 millimeters, particularly preferably between 8 millimeters and 100 millimeters.

In a particular embodiment, the fill factor of the luminous film is between 5 and 50%, in particular between 7 and 25%, particularly preferably between 9 and 15%, with homogeneous illumination.

An embodiment is preferred in which the luminous film thickness is 0.1 millimeters to 40 millimeters, in particular 0.2 millimeters to 30 millimeters, particularly preferably 0.3 millimeters to 20 millimeters. The thickness of the luminous film refers to the predominant film thickness without taking an optional textile layer into account.

An embodiment is particularly preferred in which the luminous film is designed to be bendable, in particular rollable. In particular, the bending and/or rolling radius is between 1 centimeter and 10 centimeters, particularly preferably between 2 centimeters and 5 centimeters.

Furthermore, an embodiment is preferred in which the controller of the light-emitting diodes is arranged on, in particular in, particularly preferably directly on, the light-emitting diodes of the luminous film. A controller arranged in this way simplifies the installation and the delivery of the luminous film and reduces the space required for attaching the luminous film.

Further advantages of the invention can be found in the description and the drawings. Likewise, the aforementioned features and those which are to be explained below can each be used individually or together in any desired combinations. The embodiments shown and described are not to be understood as an exhaustive list, but rather have exemplary character for the description of the invention.

### BRIEF DESCRIPTION OF THE DRAWINGS

FIG. 1 is a schematic view of a first embodiment of the lighting system;

FIG. 2 is a schematic view of a second embodiment of the lighting system.

### DETAILED DESCRIPTION OF THE PREFERRED EMBODIMENTS

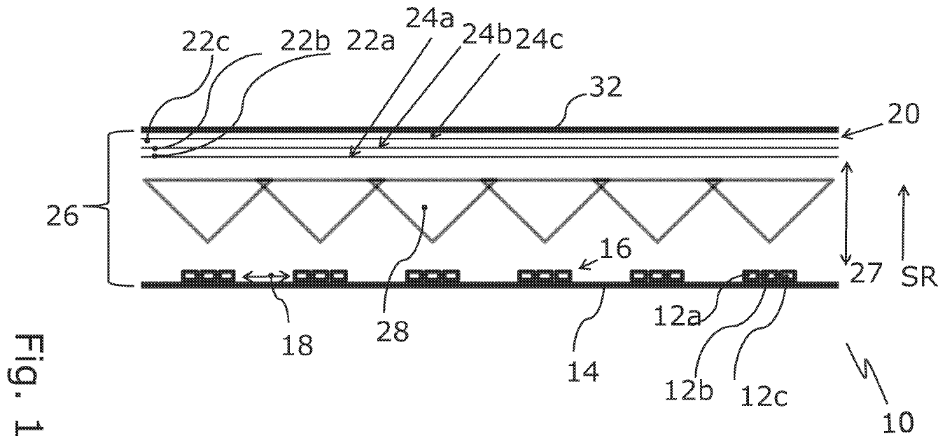

The lighting system 10 according to the invention shown in FIG. 1, for the spatially evenly distributed emission of light from light sources 12a, 12b, 12c which emit light in different spectral ranges, in a first embodiment has light sources 12a of a first type, which emit light in a first spectral range, light sources 12b of a second type, which emit light in a second spectral range, and light sources 12c of a third type, which emit light in a third spectral range. On a carrier layer 14, the light sources 12a, 12b, 12c are arranged in groups 16 which are regularly spaced apart from each other at a grouping distance 18. Each group 16 comprises three light sources 12a, 12b, 12c, each light source 12a, 12b, 12c in each group 16 belonging to a different one of the three types than the other light sources 12a, 12b, 12c in the group 16.

The lighting system 10 comprises a luminescent-material layer 20 arranged in the beam direction SR of the light sources 12a, 12b, 12c. The luminescent-material layer 20 has a first luminescent-material film 22a having a first luminescent-material 24a which is caused to luminesce by the light sources 12a of the first type. In the beam direction SR of the light sources 12a, 12b, 12c, a second luminescent-material film 22b having a second luminescent-material 24b which is caused to luminesce by the light sources 12b of the second type is arranged on the first luminescent-material film 22a. A third luminescent-material film 22c having a third luminescent-material 24c which is caused to luminesce by the light sources 12c of the third type is arranged on the second luminescent-material film 22b in the beam direction SR of the light sources 12a-12c. The first luminescent-material film 22a comprises blue-light-emitting luminescent-material 24a. The second luminescent-material film 22b comprises green-light-emitting luminescent-material 24b. The third luminescent-material film 22c comprises red-light-emitting luminescent-material 24c. All desired colors can be produced by combining the radiation emitted by the luminescent-material films 22a-22c. The first luminescent-material film 22a is arranged closer to the carrier layer 14 than the second luminescent-material film 22b. The second luminescent-material film 22b is arranged closer to the carrier layer 14 than the third luminescent-material film 22c. The height 26 of the lighting system 10 in the beam direction SR of the light sources 12a-12c is in the range of 20 mm to 100 mm.

A layer distance 27 is formed between the luminescent-material layer 20 and the light sources 12a-12c. In particular, an air layer is located between the luminescent-material layer 20 and the carrier layer 14, in which air layer light cones 28 of the various groups 16 of light sources 12a-12c can overlap for the purpose of homogenization. A diffuser layer 32 for scattering light, in particular from the light sources 12a-12c, is located on the luminescent-material layer 20 on the side of the luminescent-material layer 20 that faces away from the carrier layer 14. The light sources 12a-12c are in particular designed as light-emitting diodes.

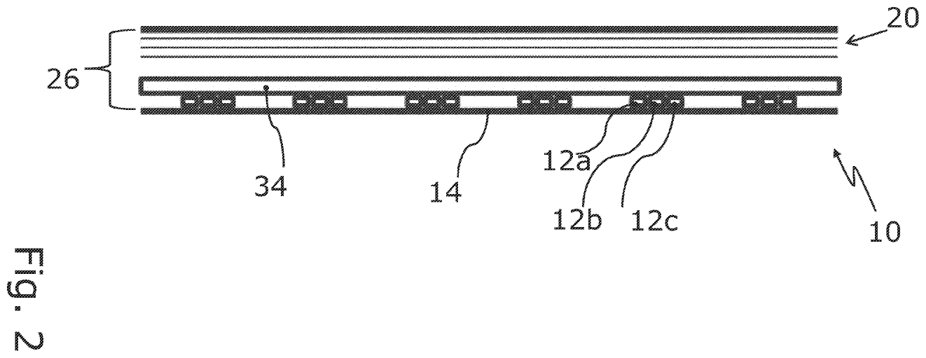

The second embodiment of the lighting system 10 that is shown in FIG. 2 comprises a micro-optical system 34 between the light sources 12a-12c and the luminescent-material layer 20, which micro-optical system is used to deflect light from the light sources 12a-12c and thus to homogenize said light. As a result, the height 26 of the lighting system 10, with a value of 3 mm to 10 mm, can be significantly smaller than in the first embodiment.

Taking all of the figures of the drawings in combination, the invention relates to a lighting system 10 for the spatially evenly distributed emission of light from first, second and third light sources 12a-12c, the spectral ranges of the light emitted by the different light sources 12a-12c being different from each other, the lighting system comprising: -a holding layer or carrier layer 14, on which the light sources 12a-12c are arranged in groups each comprising one each of the first, second and third light sources 12a-12c; and -a luminophore layer 20, which is arranged in the propagation direction of the light from the light sources 12a-12c and has a first, a second and a third luminescent-material film 22a-22c, the luminescent material 24a-24c of each luminescent-material film 22a-22c being induced to luminesce largely, more particularly exclusively, by means of the first, second or third light sources 12a-12c.

What is claimed is:

1. A lighting system for the spatially evenly distributed emission of light from light sources which emit light in different spectral ranges, comprising:
a) light sources of a first type, which emit light in a first spectral range;
b) light sources of a second type, which emit light in a second spectral range;
c) light sources of a third type, which emit light in a third spectral range;
d) a carrier layer, on which the light sources are arranged in groups which are regularly spaced apart from each other, wherein each group comprises the three light sources and in each group each light source belongs to a different one of the three types than the other light sources in the group;
e) a luminescent-material layer arranged in a beam direction of the light sources, comprising:
i) a first luminescent material in a first luminescent-material film, which is caused to luminesce by the light sources of the first type;
ii) a second luminescent material in a second luminescent-material film arranged on the first luminescent-material film in the beam direction of the light sources, which is caused to luminesce by the light sources of the second type; and
iii) a third luminescent material in a third luminescent-material film arranged on the second luminescent-material film in the beam direction of the light sources, which is caused to luminesce by the light sources of the third type.

2. The lighting system according to claim 1, wherein the luminescent-material layer is spaced apart from the light sources at a smaller distance than the distance between the groups of the light sources.

3. The lighting system according to claim 1, wherein the luminescent-material layer is arranged directly on a further component of the lighting system, in particular the carrier layer, in the direction of the carrier layer.

4. The lighting system according to claim 1, wherein a micro-optical system for deflecting light is arranged between the luminescent-material layer and the light sources.

5. The lighting system according to claim 1, wherein a diffuser layer for scattering light is arranged on the luminescent-material layer, on the side of the luminescent-material layer that faces away from the carrier layer.

6. The lighting system according to claim 1, wherein the first luminescent-material film comprises blue-light-emitting luminescent material, the second luminescent- material film comprises green-light-emitting luminescent material and the third luminescent-material film comprises red-light-emitting luminescent material, wherein the first luminescent-material film is arranged closer to the carrier layer than the second luminescent-material film and the second luminescent-material film is arranged closer to the carrier layer than the third luminescent-material film.

7. The lighting system according to claim 1, wherein the light sources are designed as light-emitting diodes.

8. The lighting system according to claim 1, wherein the light sources emit light in the blue range of the optical spectrum, wherein the maximum intensity of the light source of the first type is 405 nm to 422 nm, the maximum intensity of the light source of the second type is 425 nm to 442 nm, and the maximum intensity of the light source of the third type is 445 nm to 460 nm.

9. The lighting system according to claim 1, wherein the groups of the light sources are arranged in a rectangular pattern.

10. The lighting system according to claim 1, wherein the light sources are designed to be operated with pulse width modulation.

11. The lighting system according to claim 1, wherein the carrier layer comprises a metal, being copper.
